(19) United States
(12) Patent Application Publication
(10) Pub. No.: US 2009/0045387 A1
(43) Pub. Date: Feb. 19, 2009

(54) Resistively switching semiconductor memory

(76) Inventor: Klaus-Dieter Ufert, Unterschleissheim (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/631,055

(22) PCT Filed: Sep. 7, 2005
(86) PCT No.: PCT/EP2005/054410

§ 371 Date: Oct. 14, 2008

(30) Foreign Application Priority Data
Sep. 27, 2004 (DE) 10 2004 046 804.4

(51) Int. Cl. H01L 45/00; H01L 21/06

(52) U.S. Cl. 257/4; 438/102; 257/E45.002; 257/E21.068

(57) ABSTRACT

One embodiment provides a non-volatile semiconductor memory with CBRAM memory cells at which there exists, between the Ag-doped GeSe layer and the Ag top electrode, a chemically inert barrier layer improving the switching properties of the CBRAM memory cell. The active matrix material layer of the memory cell includes a GeSe/Ge:H double layer with a vitreous GeSe layer and an amorphous Ge:H layer. The amorphous Ge:H layer is positioned between the GeSe layer and the second electrode. Thus, the forming of AgSe conglomerates in the Ag doping and/or electrode layer is inhibited, so that precipitations are prevented and a homogeneous deposition of the silver doping layer is enabled. By means of the GeSe/Ge:H double layer system, the resistive non-volatile storage effect of the CBRAM memory cell is, on the one hand, preserved and, on the other hand, the chemical stability of the top electrode positioned thereabove is ensured by means of the thin Ge:H layer.

### BACKGROUND

One aspect of the invention relates to a semiconductor memory with resistively switching memory cells. An aspect of the invention further relates to a method for manufacturing a semiconductor memory device with non-volatile, resistively switching memory cells.

In a semiconductor memory device, a cell field consisting of a plurality of memory cells and a matrix of column and row supply lines or word and bit lines, respectively, is usually built up. The actual memory cell is positioned at the crosspoints of the supply lines that are made of electroconductive material. The column and row supply lines or word and bit lines, respectively, are each electrically connected with the memory cell via an upper electrode or top electrode and a lower electrode or bottom electrode. To perform a change of the information content in a particular memory cell at the addressed crosspoint, or to recall the content of the memory cell, the corresponding word and bit lines are selected and impacted either with a write current or with a read current. To this end, the word and bit lines are controlled by appropriate control means.

A plurality of kinds of semiconductor memories are known, e.g. a RAM (Random Access Memory) including a plurality of memory cells that are each equipped with a capacitor which is connected with a so-called selection transistor. By selectively applying a voltage at the corresponding selection transistor via the column and row supply lines, it is possible to store electric charge as an information unit (bit) in the capacitor during a write process and to recall it again during a read process via the selection transistor. A RAM memory device is a memory with optional access, i.e. data can be stored under a particular address and can be read out again under this address later.

Another kind of semiconductor memories are DRAMs (Dynamic Random Access Memories) which comprise in general only one single, correspondingly controlled capacitive element, e.g. a trench capacitor, with the capacitance of which one bit each can be stored as charge. This charge, however, remains for a relatively short time only in a DRAM memory cell, so that a so-called “refresh” must be performed regularly, e.g. approximately every 64 ms, wherein the information content is written in the memory cell again.

Contrary to this, the memory cells of so-called SRAMS (Static Random Access Memories) usually include a number of transistors each. In contrast to DRAMs, no “refresh” has to be performed in the case of SRAMs since the data stored in the transistors of the memory cell remain stored as long as an appropriate supply voltage is fed to the SRAM. Only in the case of non-volatile memory devices (NVMs), e.g. EPROMs, EEPROMs, and flash memories do the stored data remain stored even when the supply voltage is switched off.

The presently common semiconductor memory technologies are primarily based on the principle of charge storage in materials produced by standard CMOS (complement metal oxide semiconductor) processes. The problem of the leaking currents in the memory capacitor existing with the DRAM memory concept, which results in a loss of charge or a loss of information, respectively, has so far been solved insufficiently only by the permanent refreshing of the stored charge. The flash memory concept underlies the problem of limited write and read cycles with barrier layers, wherein no optimum solution has been found yet for the high voltages and the slow read and write cycles.

Since it is generally intended to accommodate as many memory cells as possible in a RAM memory device, one has been trying to realize them as simple as possible and on the smallest possible space, i.e. to scale them. The previously employed memory concepts (floating gate memories such as flash und DRAM) will, due to their functioning that is based on the storing of charges, presumably meet with physical scaling limits within foreseeable time. Furthermore, in the case of the flash memory concept, the high switching voltages and the limited number of read and write cycles, and in the case of the DRAM memory concept the limited duration of the storage of the charge state, constitute additional problems.

As approaches for solving these problems, so-called CBRAM (CB=Conductive Bridging RAM) memory cells have recently become known in prior art, in which it is possible to store digital information by a resistive switching process. The CBRAM memory cell may be switched between different electric resistance values by bipolar electric pulsing. In the simplest embodiment, such an element may be switched between a very high (e.g. in the GOhm range) and a distinctly lower resistance value (e.g. in the kOhm range) by applying short current or voltage pulses. The switching rates may be less than a microsecond. In the case of CBRAM memory cells, an electrochemically active material, e.g. a so-called chalcogenide material of germanium (Ge), selenium (Se), copper (Cu), sulphur (S), and/or silver (Ag), is present in a volume between an upper electrode or top electrode and a lower electrode or bottom electrode, for instance, in a GeSe, GeS, AgSe, or CuS compound. The above-mentioned switching process is, in the case of the CBRAM memory cell, based on principle on the fact that, by applying appropriate current or voltage pulses of specific intensity and duration at the electrodes, elements of a so-called deposition cluster continue to increase in volume in the active material positioned between the electrodes until the two electrodes are finally bridged in an electroconductive manner, i.e. are electroconductively connected with each other, which corresponds to the electroconductive state of the CBRAM cell.

By applying correspondingly inverse current or voltage pulses, this process may be reversed again, so that the corresponding CBRAM memory cell can be returned to a non-conductive state. This way, a “switching over” between a state with a higher electroconductivity of the CBRAM memory cell and a state with a lower electroconductivity of the CBRAM memory cell may be achieved.

The switching process in the CBRAM memory cell is substantially based on the modulation of the chemical composition and the local nanostructure of the chalcogenide material doped with a metal, which serves as a solid body electrolyte and a diffusion matrix. The pure chalcogenide material typically has a semiconductor behavior and has a very high electric resistance at room temperature, said electric resistance being by magnitudes, i.e. decimal powers of the ohmic resistance value higher than that of an electroconductive metal. By the current or voltage pulses applied via the electrodes, the steric arrangement and the local concentration of the ionically and metallically present components of the mobile element in the diffusion matrix is modified. Due to that, the so-called bridging, i.e. an electrical bridging of the volume between the electrodes of metal-rich depositions, may be caused, which modifies the electrical resistance of the CBRAM memory cell by several magnitudes in that the ohmic resistance value is reduced by several decimal powers.

The surfaces of vitreous GeSe layers of the chalcogenide material that are deposited by means of sputtering methods always also have an amorphous structure and frequently contain superfluous selenium that is poorly bound with respect to the valency bond with germanium. In a method that his known from the document US2003/0155606, a tempering process is performed at 250° C. in an oxygen atmosphere to oxidize the selenium at the layer surface of the GeSe layer and to evaporate it. The disadvantage of this method consists in that the entire memory device is heated with this tempering, so that an undesired modification of the layer characteristics or interface interdiffusions may occur. Moreover, the thermal energies that are employed with this method for dissolving the selenium agglomerations lie within the meV range. In this energy range, however, only those selenium atoms that are very weakly bound, i.e. that are practically unbound, can be deactivated. Weakly bound selenium atoms or selenium atoms that are conglomerated like clusters cannot be removed with this known method and thus lead to the formation of AgSe conglomerates in the Ag doping and electrode layer.

In another method known from US2003/0045049, the treatment of the surface with oxygen or hydrogen plasma or other chemicals is suggested so as to generate a passivation layer on the GeSe layer. The only object of this method, however, is to form a passivation layer at the surface of the Ag-doped GeSe layer. The oxide passivation layers that are formed with different oxygen treatments tend to crystallize at low temperatures already. The oxide layer therefore does not behave chemically inert to the Ag electrode, i.e. the formation of silver oxide may take place at the barrier face of the Ge oxide layer with the Ag electrode, which is of disadvantage for the function of the CBRAM memory cell. Furthermore, the passivation layer that has to be sufficiently chemically compact to be able to prevent the formation of conglomerates also forms an electronic barrier modifying or inhibiting the contact to the top electrode and thus the switching behavior.

### SUMMARY

One embodiment of the present invention provides a non-volatile semiconductor memory that stands out by a good scalability (nanoscale dimensions). One aspect of the present invention consists in providing a non-volatile semiconductor memory device that guarantees low switching voltages at low switching times and enables a high number of switching cycles with good temperature stability. One aspect of the present invention consists in providing a CBRAM memory cell in which there is provided, between the Ag-doped GeSe layer and the Ag top electrode, a chemically inert barrier layer that improves the switching properties of the CBRAM memory cell.

One embodiment of the present invention provides a semiconductor memory with resistively switching, non-volatile memory cells that are each arranged at the crosspoints of a memory cell matrix of electric supply lines that are each connected with the memory cell via a first electrode and a second electrode. The memory cell includes a plurality of material layers with at least one active matrix material layer having, as an ionic conductor of the memory cell, utilizing the ion drift in the matrix material layer, a resistively switching property between two stable states. The memory cell includes a GeSe/Ge:H double layer with a vitreous GeSe layer and an amorphous Ge:H layer, and wherein the amorphous Ge:H layer is positioned between the GeSe layer and the second electrode.

One embodiment of the invention specifies a structure of the layer matrix of a CBRAM memory cell which is positioned between the electrodes of the column and row supply lines or the word and bit lines, respectively, wherein the ionic conductor of the CBRAM memory cell is designed as GeSe/Ge:H double layer system that comprises a vitreous GeSe layer and an amorphous Ge:H layer positioned thereabove. By means of the GeSe/Ge:H double layer system, the resistive non-volatile storage effect of the CBRAM memory cell is, on the one hand, preserved and, on the other hand, by means of the thin Ge:H layer that contains germanium (Ge) and hydrogen (H), the chemical stability of the top electrode positioned thereabove is ensured, which is, in one of the last coating processes, manufactured preferably of silver (Ag). By means of the GeSe/Ge:H double layer system according to the present invention, the forming of AgSe conglomerates in the Ag doping and/or electrode layer is inhibited, so that precipitations are prevented and a homogeneous deposition of the silver doping layer is enabled.

One method of the invention for manufacturing a resistively switching memory cell includes an active material that is adapted to be placed in a more or less electroconductive state by means of electrochemical switching processes. The method includes at least the following steps:
generating a first electrode;
depositing a GeSe/Ge:H double layer and thus generating an active matrix material layer;
doping the active matrix material layer with a mobile doping material in the active material in a doping process;
diffusing the mobile doping material into the active matrix material layer; and
generating a second electrode.

In contrast to the above-described prior art methods, in one embodiment of the method the GeSe/Ge:H double layer is deposited prior to the process step of Ag doping and thus forms the entire active memory layer matrix into which the Ag ionic conductor is then incorporated by means of photo diffusion. Thus, the surface layer of the double layer consists of an amorphous Ge:H compound that is temperature-stable and behaves chemically inert vis-à-vis silver. The inventive method for manufacturing a CBRM memory cell avoids the performing of a tempering process step in which the doped silver may diffuse through the GeSe matrix out of control and may thus short-circuit the CBRAM memory cell.

Due to the manufacturing method according to one embodiment of the present invention, an electronic barrier such as it may form at the oxide passivation layer and the Ag top electrode, is not possible at the barrier face between the GeSe/Ge:H double layer and the electrode. The reason for this is that the Ag photo diffusion is not influenced by the thin, amorphous Ge:H layer and that the Ge:H layer is, due to the Ag atoms or ions that are available at high concentration in this layer, of good electroconductivity to the Ag top electrode.

In one embodiment of the GeSe/Ge:H double layer generated by one embodiment of the inventive method consists in that the double layer can be manufactured in the same facility and without intermediate ventilation in one process step by means of reactive sputtering of a GeSe and Ge target in an inert gas or inert gas/hydrogen mixture. Thus, the deposition of the GeSe/Ge:H double layer system on the GeSe layer may be performed in one common process step without an intermediate filling or the use of a different facility being necessary. Alternatively, it is possible to deposit this second portion of the GeSe/Ge:H double layer by means of plasma activation of the GeH₄ reactive gas in a reactive sputtering process or by means of PECVD (Plasma Enhanced Chemical Vapor Deposition).

In the above-described prior art methods, the passivation layer is deposited after the photo diffusion only, or a tempering process in oxygen atmosphere is performed subsequently, respectively. In one embodiment of the inventive method, however, a deposition of the Ge:H layer is basically also possible on the GeSe layer that has already been Ag-doped since the Ag-doped GeSe layer is no oxide layer.

One advantage of the GeSe/Ge:H double layer system further lies in the chemically inert nature of the barrier face, the electronically undisturbed connection between the top electrode and the ionic conductor in the GeSe/Ge:H matrix layer, and in the improved temperature resistance and in the reduced manufacturing efforts.

Advantages of one embodiment of the method for manufacturing a CBRAM memory cell according to embodiments of the invention are consequently substantially based on the forming of a GeSe/Ge:H double layer matrix into which the Ag ionic conductor is diffused. Due to the similarity of the structures of the amorphous, vitreous GeSe layer and the amorphous Ge:H layer, the subsequent photo diffusion process by means of which the silver is incorporated into the GeSe/Ge:H double layer matrix is not influenced. By the spatial separation of the GeSe layer to the Ag top electrode due to the chemical barrier to the Ag top electrode which is formed by the Ge:H layer, there is no reaction partner for the silver, in particular no selenium, available, so that the forming of conglomerates in the Ag electrode layer is prevented. The initially described switching properties of the GeSe layer matrix on which the resistive non-volatile storage effect of the CBRAM memory cell is based are not modified by the thin, amorphous Ge:H layer. Moreover, the amorphous Ge:H layer is more temperature-stable than the GeSe layer or an additional oxidic passivation layer and thus improves the temperature resistance of the inventive CBRAM memory device in subsequent process steps.

The above-explained advantages of the GeSe/Ge:H double layer are important for the stable function of the CBRAM memory device. The forming of the GeSe/Ge:H double layer may be achieved by the modification of known processes for the manufacturing of a GeSe:Ag resistive, non-volatile CBRAM memory device. In a sputter coating facility, e.g. the facility ZV 6000 of the Company Leybold or similar facilities of the Company KDF, three different sputter targets may be used without interruption of the vacuum. For manufacturing the GeSe/Ge:H:Ag memory device, a GeSe, Ge and Ag target are, for instance, installed in a sputter facility of this kind.

In one embodiment, the wafers as used already include structures for a W bottom electrodes and vias in the isolator layer with the appropriate dimensions. In the first part of the process step for manufacturing the double layer, the GeSe layer is deposited in the prefabricated vias of the memory device by means of rf magnetron sputtering of a GeSe connection target. To this end, Argon is commonly used as sputter gas at a pressure of approx. 4 to 5×10⁻³ mbar and a HF sputter performance in the range of 1 to 2 kW. The layer thickness generated by this is approx. 40 nm to 45 nm. In the second part of the process step, the elementary Ge target is sputtered instead of the GeSe target.

For the layer deposition of the Ge:H layer, a reactive inert gas/hydrogen mixture is used, wherein the hydrogen reacts on the layer surface with the germanium to yield Ge:H. In this second partial step of the sputter process, the same pressure and the same rf performance may be used as in the first partial step, wherein layer thickness generated in the second partial step should lie in the range of 5 nm to 10 nm. For the deposition of Ge:H, a similar sputter process may be used as for the deposition of absorber material for thin layer solar cells. In the result of these processes, a GeSe/Ge:H double layer matrix according to the present invention is generated.

In a subsequent process, silver (Ag) is deposited as a doping material on the GeSe/Ge:H double layer generated, and is subsequently diffused into the GeSe/Ge:H matrix by means of photo diffusion. For completing the CBRAM memory device, the Ag top electrode is deposited from the Ag element target in an inert gas by means of dc magnetron sputtering.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts. In the following, the invention will be explained by means of a preferred embodiment and the enclosed drawing.

FIG. 1 illustrates the schematic structure of a CBRAM memory cell with a GeSe/Ge:H double layer matrix in one embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

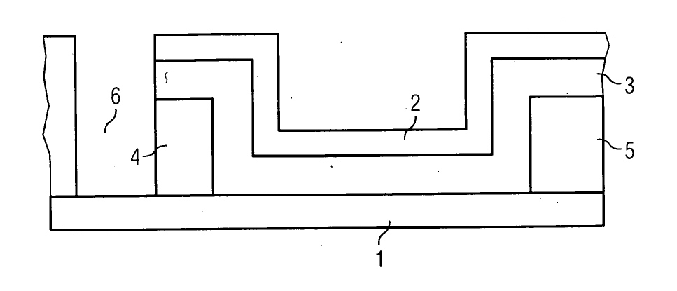

FIG. 1 schematically illustrates the inclusion of the GeSe/Ge:H double layer in the via of the inventive CBRAM memory device. The wafers as used already include structures for a W bottom electrode and corresponding vias in the isolator layer with the required dimensions.

The CBRAM memory cell illustrated in the FIGURE includes a layer stack of material layers which is built up on a substrate. The layers are manufactured in the above-described manner in a plurality of method steps according to one embodiment of the present invention. The bottom layer constitutes a first electrode or bottom electrode 1 while the top layer consists of a second electrode or top electrode 2. Via the two electrodes 1 and 2, the layer stack of the CBRAM memory cell is connected with the electric supply lines, the column and row supply lines or word and bit lines, respectively, of the semiconductor memory. The electrodes 1 and 2 are each manufactured of silver in a sputter process by using an Ag sputter target.

An active matrix material layer 3 including a GeSe/Ge:H double layer is positioned between the electrodes 1, 2. The matrix material layer 3 is doped with silver ions and has an amorphous, micromorphous, or microcrystalline structure. On the matrix material layer 3 there is positioned a doping layer (not illustrated) serving to dope the matrix material layer 3 with silver ions, and on the doping layer there is positioned the layer of the second electrode 2.

A contact hole 6 enabling a contacting of the bottom electrode 1 from the top is provided laterally next to the material layers 1, 2, 3 of the CBRAM memory cell. The material layers of the memory cell are limited laterally by a dielectric 4, 5 that is positioned between the contact hole 6 and the material layers of the memory cell.

The GeSe/Ge:H double layer includes a GeSe layer and a Ge:H layer positioned thereabove, so that the Ge:H layer is positioned between the GeSe layer and the second electrode or top electrode 2, respectively. During the manufacturing process, the GeSe/Ge:H double layer matrix is initially generated, into which the Ag ionic conductor is subsequently diffused by means of a photo diffusion process. Due to the similarity in the structures of the amorphous, vitreous GeSe layer and the amorphous Ge:H layer, the subsequent photo diffusion process by means of which the silver is incorporated into the GeSe/Ge:H double layer matrix is not influenced.

By the spatial separation of the GeSe layer from the Ag top electrode due to the chemical barrier of the thin, amorphous Ge:H layer, the forming of silver conglomerates on the active matrix material layer 3 is effectively prevented, so that the switching properties of the CBRAM memory cell are improved. Moreover, the Ge:H layer is more temperature-stable than the GeSe layer and thus improves the temperature resistance of the inventive CBRAM memory device in subsequent process steps.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1-22. (canceled)

23. A semiconductor memory comprising:
resistively switching, non-volatile memory cells each positioned at the crosspoints of a memory cell matrix constructed of electric supply lines that are each connected with the memory cell via a first electrode and a second electrode;
wherein the memory cell comprises a plurality of material layers with at least one active matrix material layer having, as an ionic conductor of the memory cell, utilizing the ion drift in the matrix material layer, a resistively switching property between two stable states;
wherein the memory cell comprises a GeSe/Ge:H double layer with a vitreous GeSe layer and an amorphous Ge:H layer; and
wherein the amorphous Ge:H layer is positioned between the GeSe layer and the second electrode.

24. The semiconductor memory according to claim 23, wherein the matrix material layer consists of a chemically inert and porous, amorphous, micromorphous, or monocrystalline matrix material with structure vacancies which has a bistable behavior due to its ionic conductivity, so that the memory cell is adapted to assume, under the influence of an electric field applied via the electric supply lines, two stable states with different mobility of ions present in the matrix material layer and with different electric resistances.

25. The semiconductor memory according to claim 23, wherein the silicon matrix material layer is doped with alkali, earth alkali, and/or metal ions, in particular with silver ions.

26. The semiconductor memory according to claim 23, wherein said material layers of the memory cell are arranged one above the other, side by side, or in some other orientation in a sandwich-like layer stack on a semiconductor substrate.

27. The semiconductor memory according to claim 23, wherein the memory cell is electrically contacted by the electric supply lines from a first side via a first electrode or bottom electrode and from another side that is opposite to the first electrode, via a second electrode or top electrode.

28. The semiconductor memory according to claim 23, wherein at least one contact hole for contacting said bottom electrode is provided laterally next to said material layers of the memory cell.

29. The semiconductor memory according to claim 28, wherein the material layers of the memory cell are limited laterally by a dielectric that is positioned between said contact hole and said material layers of the memory cell.

30. The semiconductor memory according to claim 23, wherein the resistively switching, non-volatile memory cell comprises at least of the following material layers:
a first electrode;
an amorphous, micromorphous, or microcrystalline matrix material layer doped with alkali, earth alkali, or metal ions;
a GeSe layer;
a Ge:H layer;
a doping layer; and
a second electrode.

31. The semiconductor memory according to claim 23, wherein the matrix material layer is doped with silver ions and the doping layer is a silver doping layer.

32. A method for manufacturing a resistively switching memory cell comprising an active material that is adapted to be placed in a more or less electroconductive state by means of electrochemical switching processes, the method comprising:
generating a first electrode;
depositing a GeSe/Ge:H double layer and thus generating an active matrix material layer;
doping the active matrix material layer with a mobile doping material in the active material in a doping process;
diffusing the mobile doping material into the active matrix material layer; and
generating a second electrode.

33. The method according to claim 32, wherein silver is used as mobile material or doping material, respectively, which is diffused into said active matrix material layer preferably by means of photo diffusion.

34. The method according to claim 32, wherein the depositing the GeSe/Ge:H double layer comprises:
depositing the GeSe layer in a first partial step; and
depositing the Ge:H layer in a second partial step.

35. The method according to claim 32, wherein the deposition of the Ge:H layer is performed by means of plasma activation of a GeH₄ reactive gas in a reactive sputtering process or by means of a PECVD (Plasma Enhanced Chemical Vapor Deposition) process.

36. The method according to claim 32, wherein the GeSe layer is deposited preferably in prefabricated vias by means of a sputtering process making use of a GeSe connection target.

37. The method according to claim 32, wherein, for generating the GeSe layer, a rf magnetron sputtering process is performed, preferably by using argon as sputter gas at a pressure of approx. 4 to 5×10⁻³ mbar and a HF sputter performance in the range of 1 to 2 kW.

38. The method according to claim 32, wherein the generated layer thickness of the GeSe layer is approx. 40 nm to 45 nm.

39. The method according to claim 32, wherein, for generating the Ge:H layer, a sputtering process is performed making use of an elementary Ge target and a reactive inert gas/hydrogen mixture.

40. The method according to claim 32, wherein, for generating the Ge:H layer, a rf magnetron sputtering process is performed at a pressure of approx. 4 to 5×10⁻³ mbar and a HF sputter performance in the range of 1 to 2 kW.

41. The method according to claim 32, wherein the generated layer thickness of the Ge:H layer is approx. 5 to 10 nm.

42. The method according to claim 32, wherein said second electrode is generated of silver by means of DC magnetron sputtering making use of an Ag element target and an inert gas as sputter gas.

43. A system with a memory device comprising at least a semiconductor memory with memory cells, the memory cells comprising:
a first electrode coupled to a first supply line;
a second electrode coupled to a second supply line; and
means between the first and second electrodes for utilizing ion drift of a matrix material with a resistively switching property to form two stable states.

44. The system of claim 43 further comprising a GeSe/Ge:H double layer with a vitreous GeSe layer and an amorphous Ge:H layer and wherein the amorphous Ge:H layer is positioned between the GeSe layer and the second electrode.

45. A system with a memory device comprising at least a semiconductor memory with memory cells manufactured according to claim 32.
